(19) United States
(12) Patent Application Publication
(10) Pub. No.: US 2015/0192637 A1
(43) Pub. Date: Jul. 9, 2015

(54) Use of a (Digital) PUF for Implementing Physical Degradation/Tamper Recognition for a Digital IC

(71) Applicant: SIEMENS AKTIENGESELLSCHAFT, München (DE)

(72) Inventors: Rainer Falk, Poing (DE); Andreas Mucha, Munchen (DE)

(21) Appl. No.: 14/415,369

(22) PCT Filed: Jun. 5, 2013
(86) PCT No.: PCT/EP2013/061586

§ 371 Date: Jan. 16, 2015

(30) Foreign Application Priority Data
Jul. 17, 2012 (DE) 10 2012 212 471.3

(51) Int. Cl. G01R 31/28; H03K 19/003

(52) U.S. Cl. CPC G01R 31/2855; H03K 19/003

(57) ABSTRACT

An integrated circuit configured for malfunction detection includes an integrity sensor and a test unit. The integrity sensor is based on a physical, unclonable function. The test unit is configured to send a challenge signal to the integrity sensor, and to determine information about a degradation of the integrated circuit. The information is based on a response signal subsequently generated by the physical, unclonable function and sent by the integrity sensor to the test unit.

### RELATED APPLICATIONS

This application is the National Stage of International Application No. PCT/EP2013/061586, filed Jun. 5, 2013, which claims the benefit of German Patent Application No. DE 102012212471.3, filed Jul. 17, 2012. The entire contents of both documents are hereby incorporated herein by reference.

### TECHNICAL FIELD

The present teachings relate generally to physical degradation and tamper recognition for an integrated circuit (IC).

### BACKGROUND

As used herein, terms such as “IC,” “chip,” “integrated semiconductor chip,” “semiconductor IC,” “integrated circuit,” “digital IC,” “digital chip,” and “semiconductor” are used synonymously with the term “integrated circuit.”

As used herein, terms such as “tamper verification unit,” “TVU,” and “Deg-Ver” are used synonymously with the term “checking unit.”

As used herein, terms such as “IC integrity sensor,” “PUF sensor,” “tamper sensor,” “on-chip tamper sensor,” “PUF tamper sensor,” and “PTS” are used synonymously with the term “integrity sensor.”

As used herein, terms such as “PUF,” “degradation PUF,” “DegPUF,” “physically unclonable function,” “physical one-way function,” and “tamper sensor PUF” are used synonymously with the term “physical unclonable function.”

The phrase “condition monitoring” for a machine refers to measurement of machine condition by a sensor system (e.g., oscillations, temperatures, position/proximity, etc.). Condition monitoring facilitates need-oriented maintenance (e.g., predictive maintenance) or safety shutdown. The phrase “structural health monitoring” for static components refers to ascertainment of mechanical robustness of, for example, wind turbines or structures.

A physical unclonable function (PUF) may also be referred to as a physically unclonable function, a hardware one-way function, a hardware fingerprint function, or a device fingerprint function. Physical unclonable functions are used to reliably identify objects based on their intrinsic physical properties (e.g., properties that are individual to each specimen or type). A physical property of an article (e.g., a semiconductor IC) is used as an individual “fingerprint.” The authentication of an object is based on an associated response value being returned. The response value is returned based on a challenge value by a PUF function that is defined or parameterized by physical properties. Physical unclonable functions provide a space-saving and inexpensive way of authenticating a physical object based on its intrinsic physical properties. For example, an associated response value is ascertained for a prescribed challenge value by the PUF based on object-specific physical properties of the object. If the challenge/response pairs are known, an examiner wishing to authenticate an object may identify the object as an original object by a similarity comparison between the response values that are available and the response values provided by the authenticated object.

A further example of an application of a PUF application is the chip-internal determination of a cryptographic key by a PUF.

Special PUFs (e.g., for ICs) may be put onto the IC (e.g., coating PUF, optical PUF) and thereby provide a layer above the IC that prevents access to internal (e.g., underlying) structures and that is destroyed in the event of removal. However, this approach involves specific methods of manufacture. In addition, attacks that do not damage the protective layer may not be recognized (e.g., attacks coming from the opposite side or from the side).

The PUF raw data (e.g., response) may be post-processed to compensate for random fluctuations in the PUF response (e.g., by forward error correction or by feature extraction as in conventional fingerprint authentication).

A publication entitled “Active Hardware Metering for Intellectual Property Protection and Security,” (16th USENIX Security Symposium, 2007) by Yousra M. Alkabani and Farinaz Koushanfar describes the use of a PUF to prevent “overbuilding” of semiconductor ICs. For example, the state machine for the IC to work is modified. As a result, the state machine contains a large number of states that are unnecessary for the desired operation. The starting state is ascertained by a PUF. For example, the IC starts the execution in a starting state that is dependent on random, specimen-specific properties. Only the designer of the IC may know the design specification of the state machine Thus, only the designer may feasibly ascertain for a given IC a path from the random initial state to a starting state corresponding to use of the functionality (e.g., in other words, program a manufactured IC).

A PUF structure is altered during physical manipulation, thereby facilitating tamper protection. Furthermore, PUFs may also be used when a chip does not have memory for permanently storing a cryptographic key. In such cases, specific methods of manufacture (e.g., for flash memories) or a backup battery (e.g., for SRAM memory cells) may be used.

Various physical implementations of a physical unclonable function may be used. For example, PUFs may be implemented easily and in a space-saving manner on an IC (e.g., digital or analog). A permanent key memory and the implementation of cryptographic algorithms may be avoided.

The robustness of a PUF (e.g., with regard to aging, influence of temperature) may be examined to implement a robust, reliable PUF as described, for example, in the article entitled “Differential Public Physically Unclonable Functions: Architecture and Applications” (DAC 2011, Jun. 5-10, 2011, San Diego, Calif., USA) by Potkonjak et al.

The article entitled “Device aging-based physically unclonable functions” (Design Automation Conference (DAC), pp. 288-289, June 2011) by S. Meguerdichian and M. Potkonjak describes a dynamic PUF that may be altered by aging. The dynamic PUF is not altered by natural aging but rather via the control of the user of the PUF (e.g., the user may trigger a change in the PUF behavior). As a result, reverse engineering becomes more difficult. The PUF is individualized under user control rather than by intrinsic physical variations in an IC. The proposed PUF is robust since only delayed differences above a threshold value become effective for the determination of the response value.

Many devices perform a self-test on a regular basis or on request when starting or in the course of ongoing operation. If a device is not working properly, the device may initiate countermeasures. For example, the device may stop operation (e.g., fail silent), deactivate at least one functionality, or inform maintenance personnel (e.g., by a warning indicator or a warning report). Log data may be written to an error log. Critical data (e.g., sensitive program code, configuration parameters or cryptographic keys) may be erased. In cryptographic security methods, a self-test on the crypto processes takes place prior to use. Components may be subject to an aging process that may cause failure. Integrated circuits (e.g., memory chips, ASICs, FPGAs, system on chips (SoC), CPUs, etc.) may also fail when subjected to an aging process. Industrial environments place high demands on component reliability and lifespan.

### SUMMARY AND DESCRIPTION

The scope of the present invention is defined solely by the appended claims, and is not affected to any degree by the statements within this summary.

In accordance with the present teachings, information about the aging and probability of failure of an integrated circuit may be ascertained. In addition, robust self-test function that reliably detects a malfunction in the event of aging or intentional manipulations may be provided.

The present embodiments may obviate one or more of the drawbacks or limitations in the related art. For example, in some embodiments, reliable detection of a malfunction in an IC is provided.

An integrated circuit includes an integrity sensor and a checking unit. The integrity sensor is based on a physical unclonable function. The integrity sensor is configured to receive a challenge signal and to use the challenge signal to send a response signal to the checking unit. The response signal is produced using the physical unclonable function. The checking unit is configured to receive the response signal and to use the response signal to ascertain a piece of information about degradation of the integrated circuit.

In some embodiments, the checking unit is further configured to send the challenge signal to the integrity sensor.

In some embodiments, the integrated circuit includes a separate signal generation unit that is configured to produce the challenge signal and to send the challenge signal both to the integrity sensor and to the checking unit.

In some embodiments, the checking unit is further configured to use the time profile of the piece of degradation information to distinguish whether ascertained degradation of the integrated circuit may be attributed to physical manipulation or an aging process. In some embodiments, the checking unit is further configured to store a history of ascertained pieces of information about the degradation of the integrated circuit and to distinguish abrupt changes in the history from continuous changes. Abrupt changes may be attributed to damage or manipulation, whereas continuous changes may be attributed to degradation.

If the degradation occurs suddenly or abruptly, the likelihood of damage or manipulation is increased. Aging over time may occur slowly (e.g., over months or years). The degradation value rises continuously. Time information may not be available but information relating to the degradation of the last checks may be stored (e.g., a history of the last three or ten checks) and the current value may be compared therewith.

In some embodiments, the integrated circuit includes a plurality of integrity sensors that may be in a distributed arrangement on a surface of the integrated circuit. The distributed arrangement on the surface increases security against manipulations since even a careful attacker will be faced with increased risk of damage or physical alteration to the integrity sensors.

In some embodiments, the checking unit is further configured to compare response signals from different integrity sensors and/or to distinguish between a strong correlation and a weak correlation in the response signals. When there is a plurality of integrity sensors, the information elements may be compared. In the case of age-related degradation, the degradation of different integrity sensors may be similar. In the case of physical manipulation, the integrity sensors may differ to a greater extent.

In some embodiments, an IC integrity sensor may be implemented on a digital IC based on intrinsic semiconductor properties. For example, a PUF implemented on the IC is verified by the IC itself. The PUF sensor of an IC is used to ascertain information about the degradation of the IC (e.g., as a result of aging, thermal loading, radiation loading, damage, or intentional manipulation/tampering). If there is sufficient degradation, the IC may have failed or been manipulated, and the probability of device failure increases. A PUF integrity sensor with an associated evaluation apparatus may also be used for a different objective, such as the recognition of aging processes and the recognition of physical manipulations.

If the IC has been physically degraded or manipulated, the degradation or manipulation modifies the PUF. In other words, the PUF exhibits a different input/output behavior than that of a new, intact IC. Degradation or manipulation of the IC may thus be recognized.

In some embodiments, information about the degradation may be used by the integrated circuit in different ways including the following:

provision of degradation information (e.g., via signal to external pin, internally for other assemblies of the IC, via diagnosis interface)

temporary deactivation of the IC (e.g., while degradation is present)

permanent deactivation of the IC

deactivation (permanent or temporary) of an affected partial functionality (e.g., for a plurality of integrity sensors distributed over the chip area, the affected region may be ascertained, such that only the functionality of the affected region may be deactivated); the IC deactivates itself or changes to a restricted mode of operation (e.g., restricted functionality, reduced clock frequency, narrower tolerances for the operating voltage monitoring), wherein reliable operation with reduced performance may continue

activation of a restricted mode of operation (e.g., reduced clock frequency; reduced functionality; customization of the voltage regulation, such as raising the minimum voltage level)

erasure of stored data (e.g., cryptographic key material)

the IC provides information externally, such that IC-external clock generation or voltage monitoring may react thereto

the information is provided via a diagnosis interface (e.g., via a data communication interface); the information may be written to an internal error memory (e.g., that may be read via a diagnosis interface); device monitoring (e.g., remote condition monitoring) may derive information that the affected device may be replaced.

The PUF integrity sensor verifies the physical intactness of the digital chip or the digital logic thereof. If the chip is physically manipulated, the PUF behavior changes. For checking, a PUF is authenticated (e.g., challenge values are applied to the PUF). Based on the response values, a comparison with stored reference data may detect an alteration. If physical manipulation is carried out (e.g., making contact by test probes) or if manipulations have been carried out on the chip structure (e.g., bypassing or severing lines), the PUF behavior changes. Thus, the PUF is not used for authenticating the IC to an outsider or for deriving a cryptographic key.

A digitally implemented PUF (e.g., a delay PUF/arbiter PUF, SRAM PUF, ring oscillator PUF, bistable ring PUF, flipflop PUF, glitch PUF, cellular nonlinear network PUF or butterfly PUF) is used to implement an on-chip tamper sensor. The on-chip tamper sensor has an advantage that the tamper sensor may be configured and manufactured “in digital form.” Thus, mixed signal processes may be avoided. The PUF is manufactured in a regular semiconductor structure using manufacturing technology provided for this purpose. In contrast to coating PUFs, a specific method of manufacture or a separate manufacturing step may be avoided. In contrast to analog sensors, the above-described PUF sensor may be implemented using the regular digital method of manufacture of the rest of the IC.

The PUF sensor is checked by the digital logic of the IC itself. The check may take place at the start (e.g., following a reset), when a given functionality (e.g., encryption engine) is activated, upon an external trigger signal, or repeatedly during the course of operation (e.g., a built-in self test).

A plurality of PUF tamper sensors may be in a distributed arrangement on the chip area. The plurality of PUF tamper sensors may be placed according to various design criteria. For example, the PUF tamper sensors may be placed in a regular structure (e.g., a grid structure) proximal to critical regions (e.g., in the chip areas, in the manner wherein cryptographic parameters are stored or cryptographic operations are executed), or with security fuses (e.g., for deactivating a JTAG interface). In some embodiments, randomized positions are determined. For programmable logic chips (FPGA), for example, the checking positions may be chosen differently for each chip or for each charge. For an ASIC with a plurality of ICs on a wafer, different positions may be implemented for the ICs that are existent on the wafer.

For multilayer chips or chip modules, a plurality of PUF sensors may be implemented in different layers of the chip. The implementation of a PUF sensor may include a plurality of layers, thereby facilitating the detection of aging or damage in just individual layers of an IC.

In some embodiments, the IC is reconfigurable or the IC has reconfigurable components. For example, a tamper sensor PUF may also jointly use regular components, such as data paths (e.g., data bus, address bus). For example, the chip is configured to a verification mode wherein individual system components are either connected up as a PUF or connected up to a PUF such that the individual system components influence the PUF output behavior. Following a successful check, the IC, or the reconfigurable components thereof, is configured in accordance with an operating configuration. As a result, a high level of protection for the components connected up to form the PUF may be achieved.

In some embodiments, a security fuse is implemented by a PUF or integrated into a PUF. A security fuse may be blown, for example, to be able to check the IC only during manufacture (e.g., JTAG interface) or to prevent stored data from being read. Security fuses today are blown and, as a result of, are physically destroyed. However, the security fuses have a relatively large physical structure and, therefore, may be bypassed when an IC is open. If a security fuse is integrated into a PUF calculation or into the implementation of a PUF, blowing involves the PUF structure being destroyed (e.g., melted) or at least modified. However, late manipulation (e.g., by bypassing) does not result in the original PUF behavior. As a result, the lack of physical manipulation of a security fuse may be verified in a manner protected against manipulation within an IC.

Instead of using the chip wiring used for regular operation as a PUF during a checking phase and using the chip wiring in regular fashion during normal operation, PUF lines may be laid parallel or close to the signal lines as PUF verification lines. The PUF verification lines may be modified in the event of physical manipulation of the signal lines. Thus, for example, contact being made with the signal lines may be recognized, thereby facilitating a check during regular use.

PUF sensors for recognizing manipulation of the digital chip are easy to manufacture and may be implemented, for example, as a design IP and as a chip in a design library for programmable logic chips (e.g., FPGA, ASIC). Special mixed-signal design and manufacturing methods may be avoided.

### BRIEF DESCRIPTION OF THE DRAWINGS

FIG. 1 shows an example of an integrated circuit in accordance with the present teachings.

FIG. 2 shows an example of an integrated circuit in accordance with the present teachings.

FIG. 3 shows an exemplary sequence of a communication between TVU and PTS for a challenge/response method in accordance with the present teachings

FIG. 4 shows an exemplary sequence of a check on an IC in accordance with the present teachings.

FIG. 5 shows an example of an integrated circuit in accordance with the present teachings, wherein DegVer and DegPUF are implemented inside the IC.

### DETAILED DESCRIPTION

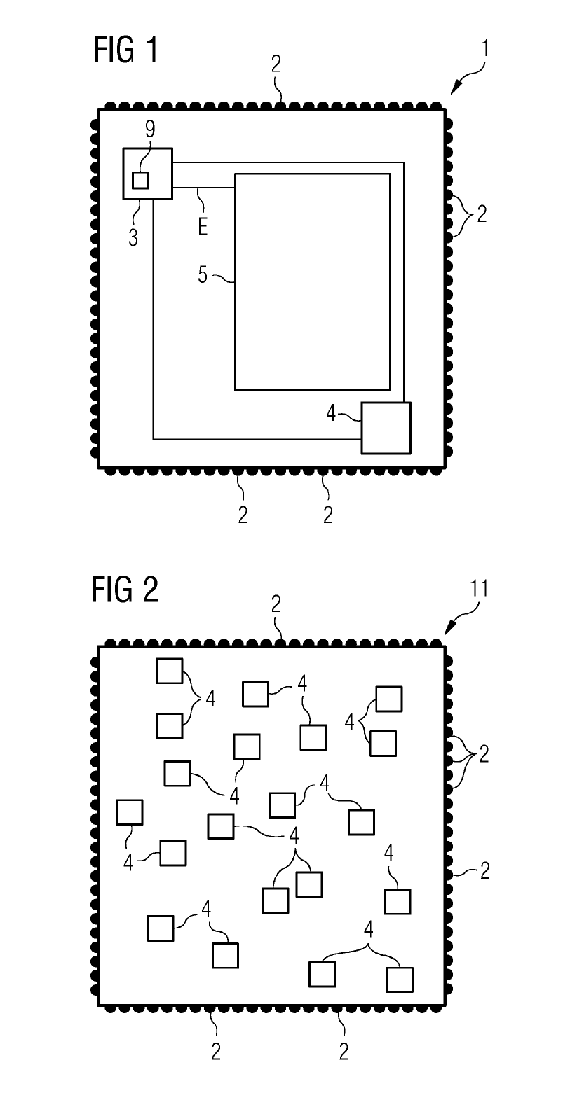

FIG. 1 shows an example of an integrated circuit 1 (a.k.a. IC, chip, or semiconductor), such as an FPGA or an ASIC, that contains a checking unit 3 (a.k.a. TVU or tamper verification unit). Contacts 2 (a.k.a. pins or interfaces) are shown at the sides of the integrated circuit 1 in FIG. 1. The contacts 2 may be used, for example, to solder the integrated circuit 1 in the form of a chip on a printed circuit board. The TVU 3 detects tampering with the IC 1 by evaluating an integrity sensor 4 (a.k.a. PUF-based tamper sensor, PUF tamper sensor or PTS). Based on a result of the check, an enable signal E is provided. The enable signal is evaluated by a “main function” block 5, for example, to enable or disable a functionality of the IC 1. As a result, a given functionality or the entire IC 1 may be deactivated. In some embodiments, some or all of the external interfaces 2 of the IC 1 may be switched to a “fail safe condition.” In some embodiments, a SafeForUse signal is provided by the IC 1 to provide a failsafe signal for additional external chips in the event of a manipulated chip 1 or in the event of a negative self-test.

The integrated circuit 1 includes the integrity sensor 4 and the checking unit 3. The integrity sensor 4 is based on a physical unclonable function 24. The checking unit 3 is configured to send the integrity sensor 4 a challenge signal C and to use a response signal R that is produced in response by the physical unclonable function 24 and sent to the checking unit 3 by the integrity sensor 4 to ascertain information about degradation of the integrated circuit IC.

The checking unit 3 is configured to use the information to ascertain further information relating to the degradation of the integrated circuit 1 caused by aging processes. In addition, the checking unit 3 is configured to use the information about the degradation to ascertain physical damage to or manipulation of the integrated circuit 1.

The checking unit 3 is configured to distinguish whether ascertained degradation of the integrated circuit 1 may be attributed to physical manipulation or an aging process. In some embodiments, the checking unit is configured to make the distinction based on a time profile of the information about the degradation. For example, the checking unit includes a memory element 9 that may be used to store a history of ascertained information about the degradation of the integrated circuit 1. The checking unit is configured to distinguish abrupt changes in the history from slowly progressive changes, and to attribute abrupt changes to damage and slowly progressive changes to degradation.

In some embodiments, the integrated circuit 1 is digital, such as a field programmable gate array (FPGA) or an application-specific integrated circuit (ASIC). The physical unclonable function 24 may be implemented in digital form.

FIG. 2 shows an embodiment of an integrated circuit 11 (a.k.a. IC, chip, or semiconductor), wherein a plurality of integrity sensors 4 (a.k.a. PUF tamper sensors or PTS) are provided on the IC 11. The integrity sensors 4 may be placed irregularly (e.g., as shown in the example of FIG. 2) or regularly (e.g., in a grid arrangement). The checking unit TVU and the main function block are not shown in FIG. 2.

The exemplary embodiment shown in FIG. 2 may be combined with variants of the exemplary embodiment shown in FIG. 1. The integrated circuit 11 includes a plurality of integrity sensors 4 that may be in a distributed arrangement on the surface of the integrated circuit 11. The checking unit 3 is configured to compare response signals R from various integrity sensors 4 and/or to distinguish between a strong correlation and a weak correlation in the response signals R. In some embodiments, the integrated circuit 1 and/or the integrated circuit 11 is reconfigurable and/or includes reconfigurable components.

The integrity sensors 4 may include regular components of a main function 5 of the integrated circuit 1 and/or the integrated circuit 11 (e.g., data paths or clock paths).

The physical unclonable function 24 may include at least one security fuse.

In some embodiments, the physical unclonable function includes lines that run parallel or close to signal lines (e.g., data paths or clock paths) that are not included by the physical unclonable function.

The degradation of the integrated circuit IC may be ascertained by the integrity sensor 4 through a comparison of the response signal R with a reference response.

The integrated circuit 1 and/or the integrated circuit 11 is configured to implement at least one of the following measures in the event of a degradation exceeding a threshold value being recognized:

provision of degradation information (e.g., via signal to external pin, internally for other assemblies of the IC, via diagnosis interface)

temporary deactivation of the IC (e.g., while degradation is present)

permanent deactivation of the IC

deactivation (permanent or temporary) of an affected partial functionality (e.g., for a plurality of integrity sensors distributed over the chip area, the affected region may be ascertained, such that only the functionality of the affected region may be deactivated)

activation of a restricted mode of operation (e.g., reduced clock frequency; reduced functionality; customization of the voltage regulation, such as raising the minimum voltage level)

erasure of stored data (e.g., key material).

In some embodiments, a PTS 4 may be implemented in a “physically” expansive manner on the IC. For example, for a delay-based PUF, the delay lines may cover large sections of the IC.

In some embodiments, a PTS includes a circuit for measuring the capacitance or impedance of individual signal connections (e.g., data/address paths) on the chip, either individually with respect to the chip ground or between selected line pairs. Alternatively, a differential measurement may be performed, wherein the measured values from various lines or line pairs are compared with one another. The lines to be compared are determined by the challenge value sent to the PUF. A specific circuit implementation of the impendence measurement may be provided by an oscillator (e.g., ring oscillator, relaxation oscillator) and a downstream counter. The frequency of the oscillator is influenced by the line capacitance.

In some embodiments, the TVU may be existent on the IC multiple times, thus avoiding an individual attack point (e.g., global enable signal) where an attacker could take action to stop the tamper protection from working. For example, a TVU may be placed close to a sensitive circuit block (e.g., cryptographic function, key memory) or even interleaved or interwoven therewith. The circuit block may receive a dedicated local enable signal from the TVU. Since a plurality of sensitive circuit blocks may be needed for the overall system to work, the difficulty of a successful attack is increased further still.

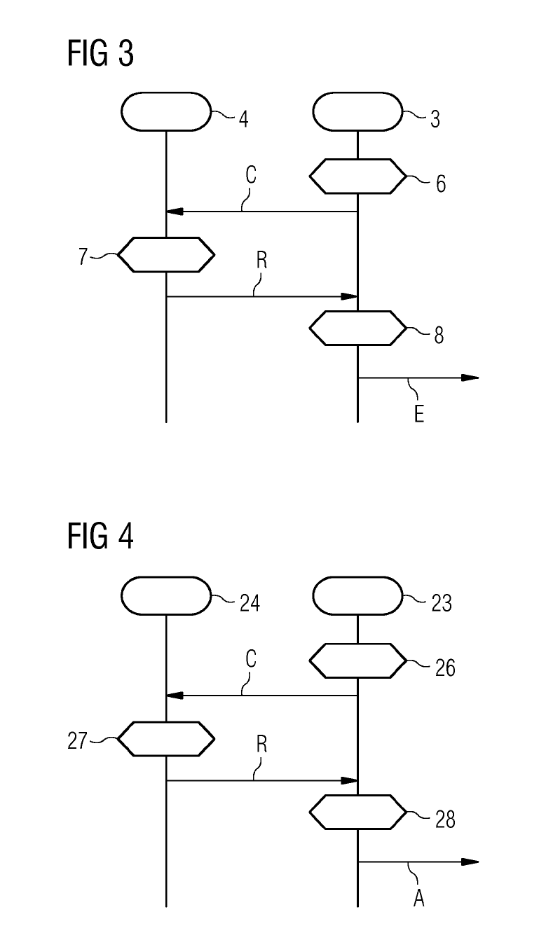

FIG. 3 shows a sequence of communication between TVU 3 and PTS 4 for a challenge/response method. In method act 6, the TVU 3 selects a challenge signal C, or a challenge value, and sends the challenge signal C or challenge value to the PTS 4. Based on the challenge signal C or challenge value sent by the TVU 3, the PTS 4 returns a response signal R or a response value. The response signal R or the response value is determined in the PTS 4 in method act 7 by a PUF. The response signal R is checked by the TVU 3 in method act 8. The checking in method act 8 may be achieved using standard methods (e.g., a similarity comparison with stored reference values). If the check is successful, the TVU 3 provides an enable signal E. A check may also take place for a plurality of challenge values.

Degradation Recognition:

Manipulations that are not intentional—but rather are caused by aging, temperature loading, or radiation—may also be recognized using a PUF integrity sensor 3 in accordance with the present teachings.

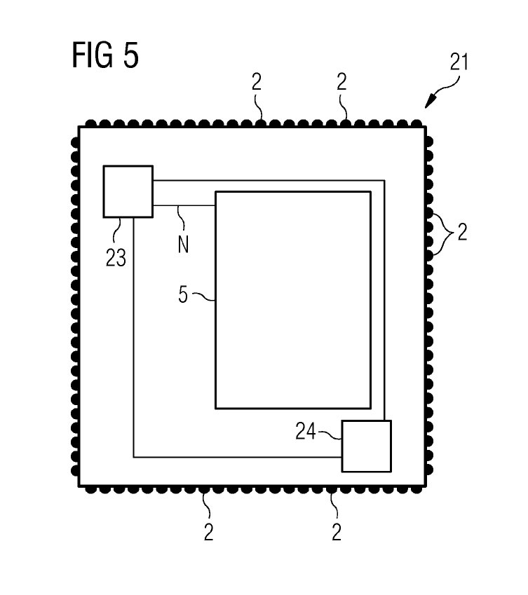

FIG. 4 shows a representative sequence of the check. The behavior of the degradation PUF 24 (a.k.a. DegPuf) is may change upon degradation of the IC. In method act 26, a degradation verification unit 23 (a.k.a. DegVer 23) selects a challenge value and sends the challenge value in a challenge message C to the DegPUF. The DegPUF determines a response value in method act 27 and sends the response value in a response message R to the DegVer 23. The DegVer 23 checks the response message R, or the response value thereof, provided by the DegPuf 24 in method act 28. For example, the DegVer 23 may perform a similarity comparison between the received response message R and a reference response, or between the received response value and a reference response value. If there is sufficient discrepancy (e.g., measured in the number of different bits, such as Hamming distance), degradation is recognized. The result may be provided as a Boolean value (e.g., true, false) in an output signal A. Alternatively, a multistage confidence value may be provided (e.g., green, yellow, red; 0.255). A plurality of measurements may be taken. The measurements may involve the use of different and/or identical challenge values C.

The DegPUF 24 is implemented on the IC to be monitored. The check (DegVer) or ascertainment of information about the degradation may be effected on the monitored IC itself or outside the monitored IC. The DegVer 23 may be implemented in hardware or software. The reference response may be captured and stored initially during production or component fitting for the IC.

FIG. 5 shows an example wherein DegVer 23 and DegPUF 24 are implemented inside an IC. A main function 5 of the IC 21 is provided with an appropriate status signal N (NoDegeneration).

In other examples (not shown), the NoDegen signal is provided externally on a signal pin of the IC. In a further example, only DegPUF is implemented on an IC and the interface to DegPUF is provided externally (e.g., via 12C, JTAG interface). The functionality DegVer may be implemented on another IC or on another computer.

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding claim—whether independent or dependent—and that such new combinations are to be understood as forming a part of the present specification.

1. An integrated circuit, comprising:
an integrity sensor; and
a checking unit;
wherein the integrity sensor is based on a physical, unclonable function, wherein the integrity sensor is configured to receive a challenge signal and to use the challenge signal to send a response signal to the checking unit, and wherein the response signal is produced using the physical unclonable function; and
wherein the checking unit is configured to receive the response signal and to use the response signal to determine first information about degradation of the integrated circuit.

2. The integrated circuit of claim 1, wherein the checking unit is further configured to use the first information to determine additional information about the degradation of the integrated circuit caused by aging processes.

3. The integrated circuit of claim 1, wherein the checking unit is further configured to use the first information about the degradation to determine physical damage to the integrated circuit or manipulation of the integrated circuit.

4. The integrated circuit of claim 1, wherein the checking unit is further configured to determine whether degradation of the integrated circuit is attributable to physical manipulation or an aging process.

5. The integrated circuit of claim 1, wherein the checking unit is further configured to use a time profile of the first information about the degradation to determine whether degradation of the integrated circuit is attributable to physical manipulation or an aging process.

6. The integrated circuit of claim 1, wherein the checking unit is further configured to store a history of determined information about the degradation of the integrated circuit, and to distinguish between abrupt changes in the history progressive changes.

7. The integrated circuit of claim 1, wherein the checking unit is further configured to attribute abrupt changes to damage and progressive changes to degradation.

8. The integrated circuit of claim 1, wherein the integrated circuit is digital.

9. The integrated circuit of claim 1, wherein the physical, unclonable function is implemented in digital form.

10. The integrated circuit of claim 1, wherein the integrated circuit comprises a plurality of integrity sensors provided in a distributed arrangement on a surface of the integrated circuit.

11. The integrated circuit of claim 10, wherein the checking unit is further configured to (a) compare response signals from different integrity sensors of the plurality of integrity sensors, (b) distinguish between a strong correlation and a weak correlation in the response signals, or (c) compare response signals from different integrity sensors of the plurality of integrity sensors and distinguish between a strong correlation and a weak correlation in the response signals.

12. The integrated circuit of claim 1, wherein the integrated circuit is reconfigurable, comprises reconfigurable components, or is reconfigurable and comprises reconfigurable components.

13. The integrated circuit of claim 1, wherein the integrity sensor is further configured to jointly use regular components of a main function of the integrated circuit.

14. The integrated circuit of claim 1, wherein the physical, unclonable function comprises at least one security fuse.

15. The integrated circuit of claim 1, wherein the physical, unclonable function comprises lines that run parallel or proximal to signal lines, and wherein the signal lines are not comprised by the physical, unclonable function.

16. The integrated circuit of claim 1, wherein the degradation of the integrated circuit is ascertainable by the integrity sensor through a comparison of the response signal with a reference response.

17. The integrated circuit of claim 1, wherein the integrated circuit is configured to implement a measure if the degradation exceeds a threshold value, wherein the measure is selected from the group consisting of provision of the first information about the degradation, temporary deactivation of the integrated circuit, permanent deactivation of the integrated circuit, deactivation of an affected partial functionality of the integrated circuit, activation of a restricted mode of operation of the integrated circuit, erasure of stored data, and combinations thereof.

18. The integrated circuit of claim 1, wherein the integrated circuit comprises a field programmable gate array.

19. The integrated circuit of claim 1, wherein the integrated circuit comprises an application-specific integrated circuit.

20. The integrated circuit of claim 13, wherein the regular components of the main function of the integrated circuit comprise data paths or clock paths.
